(19) United States
(12) Patent Application Publication
(10) Pub. No.: US 2018/0017876 A1
(43) Pub. Date: Jan. 18, 2018

(54) MICRO LED ARRAY AS ILLUMINATION SOURCE

(71) Applicant: Applied Materials, Inc., Santa Clara, CA (US)

(72) Inventors: Jang Fung CHEN, Cupertino, CA (US); Christopher Dennis BENCHER, Cupertino, CA (US)

(21) Appl. No.: 15/649,341

(22) Filed: Jul. 13, 2017

Related U.S. Application Data
(60) Provisional application No. 62/361,964, filed on Jul. 13, 2016.

(51) Int. Cl. G03F 7/20

(52) U.S. Cl. CPC G03F 7/70191; G03F 7/70591

(57) ABSTRACT

Embodiments of the present disclosure generally relate to apparatuses and systems for performing photolithography processes. More particularly, compact illumination tools for projecting an image onto a substrate are provided. In one embodiment, an illumination tool includes a microLED array including one or more microLEDs. Each microLED produces at least one light beam. The illumination tool also includes a beamsplitter adjacent the microLED array, one or more refractory lens components adjacent the beam splitter, and a projection lens adjacent the one or more refractory lens components. The mounting plate advantageously provides for compact alignment in a system having a plurality of illumination tools, each of which is easily removable and replaceable.

### CROSS-REFERENCE TO RELATED APPLICATIONS

This application claims benefit of U.S. provisional patent application Ser. No. 62/361,964, filed Jul. 13, 2016, which is herein incorporated by reference.

### BACKGROUND

### Field

Embodiments of the present disclosure generally relate to apparatuses and systems for processing one or more substrates, and more specifically to apparatuses for performing photolithography processes.

### Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels may include a layer of liquid crystal material forming pixels sandwiched between two plates. When power from the power supply is applied across the liquid crystal material, an amount of light passing through the liquid crystal material may be controlled at pixel locations enabling images to be generated.

Microlithography techniques are generally employed to create electrical features incorporated as part of the liquid crystal material layer forming the pixels. According to this technique, a light-sensitive photoresist is typically applied to at least one surface of the substrate. Then, a pattern generator exposes selected areas of the light-sensitive photoresist as part of a pattern with light to cause chemical changes to the photoresist in the selective areas to prepare these selective areas for subsequent material removal and/or material addition processes to create the electrical features.

In order to continue to provide display devices and other devices to consumers at the prices demanded by consumers, new apparatuses and approaches are needed to precisely and cost-effectively create patterns on substrates, such as large area substrates.

### SUMMARY

Embodiments of the present disclosure generally relate to apparatuses and systems for performing photolithography processes. More particularly, compact apparatuses for projecting an image onto a substrate are provided. In one embodiment, an illumination tool is disclosed. The illumination tool includes a microLED array with one or more microLED where each microLED produces at least one light beam. The illumination tool also includes a beamsplitter adjacent the microLED array, one or more refractory lens components adjacent the beamsplitter, and a projection lens adjacent the one or more refractory lens.

In another embodiment, an illumination tool is disclosed. The illumination tool includes a microLED array. The microLED array includes one or more microLED with each microLED producing at least one light beam. The illumination tool also includes a beamsplitter adjacent the microLED array, one or more refractory lens components adjacent the beamsplitter, a projection lens adjacent the one or more refractory lens, and a distortion compensator disposed between the projection lens and the beamsplitter.

In another embodiment, an illumination tool system is disclosed. The illumination tool system includes two or more states configured to hold one or more substrates and a plurality of illumination tools for patterning the one or more substrates. Each illumination tool includes a microLED array. The microLED array includes one or more microLED with each microLED producing at least one light beam. Each illumination tool also includes a beamsplitter adjacent the microLED array, one or more refractory lens components adjacent the beamsplitter, and a projection lens adjacent the one or more refractory lens.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a perspective view of a system that may benefit from embodiments disclosed herein.

FIG. 2 is a perspective schematic view of an illumination tool according to one embodiment.

FIG. 3 is a perspective view of an illumination tool according to one embodiment.

FIG. 4 is a cross-sectional view of the optical relays according to one embodiment.

FIG. 5 is a schematic view of a focus sensing mechanism according to one embodiment.

FIG. 6 is a schematic view of a microLED array according to one embodiment.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments of the present disclosure generally relate to apparatuses and systems for performing photolithography processes. More particularly, compact illumination tools for projecting an image onto a substrate are provided. In one embodiment, an illumination tool includes a microLED array including one or more microLEDs. Each microLED produces at least one light beam. The illumination tool also includes a beamsplitter adjacent the microLED array, one or more refractory lens components adjacent the beam splitter, and a projection lens adjacent the one or more refractory lens components. The mounting plate advantageously provides for compact alignment in a system having a plurality of illumination tools, each of which is easily removable and replaceable.

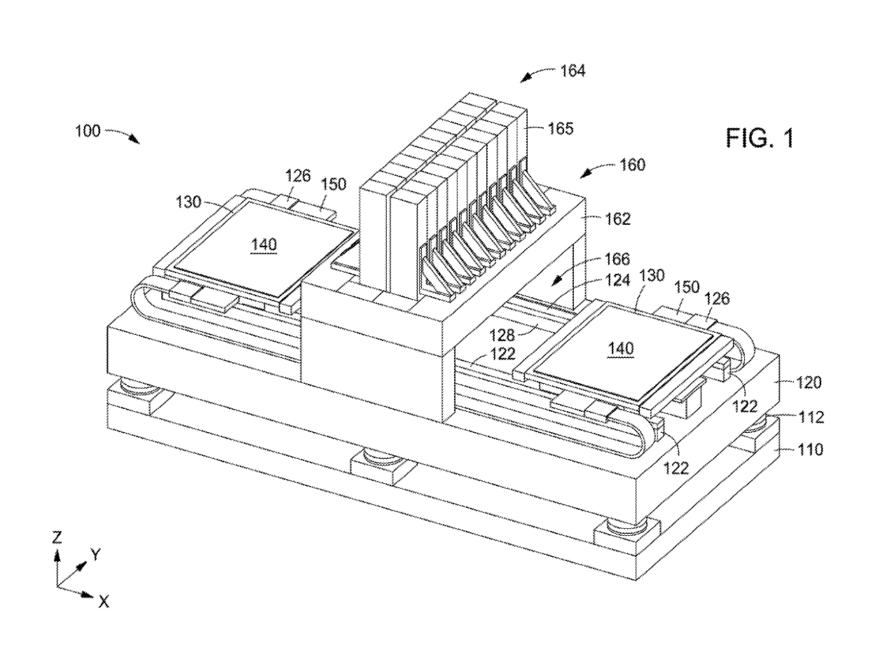

FIG. 1 is a perspective view of a system 100 that may benefit from embodiments disclosed herein. The system 100 includes a base frame 110, a slab 120, two or more stages 130, and a processing apparatus 160. The base frame 110 may rest on the floor of a fabrication facility and may support the slab 120. Passive air isolators 112 may be positioned between the base frame 110 and the slab 120. The slab 120 may be a monolithic piece of granite, and the two or more stages 130 may be disposed on the slab 120. A substrate 140 may be supported by each of the two or more stages 130. A plurality of holes (not shown) may be formed in the stage 130 for allowing a plurality of lift pins (not shown) to extend therethrough. The lift pins may rise to an extended position to receive the substrate 140, such as from one or more transfer robots (not shown). The one or more transfer robots may be used to load and unload a substrate 140 from the two or more stages 130.

The substrate 140 may, for example, be made of glass and be used as part of a flat panel display. In one embodiment, the substrate 140 may comprise quartz. The substrate 140 may be made of other materials. In some embodiments, the substrate 140 has a photoresist layer formed thereon. A photoresist is sensitive to radiation and may be a positive photoresist or a negative photoresist, meaning that portions of the photoresist exposed to radiation will be respectively soluble or insoluble to photoresist developer applied to the photoresist after the pattern is written into the photoresist. The chemical composition of the photoresist determines whether the photoresist will be a positive photoresist or negative photoresist. For example, the photoresist may include at least one of diazonaphthoquinone, a phenol formaldehyde resin, poly(methyl methacrylate), poly(methyl glutarimide), and SU-8. In this manner, the pattern may be created on a surface of the substrate 140 to form the electronic circuitry.

The system 100 may further include a pair of supports 122 and a pair of tracks 124. The pair of supports 122 may be disposed on the slab 120, and the slab 120 and the pair of supports 122 may be a single piece of material. The pair of tracks 124 may be supported by the pair of the supports 122, and the two or more stages 130 may move along the tracks 124 in the X-direction. In one embodiment, the pair of tracks 124 is a pair of parallel magnetic channels. As shown, each track 124 of the pair of tracks 124 is linear. In other embodiments, the track 124 may have a non-linear shape. An encoder 126 may be coupled to each stage 130 in order to provide location information to a controller (not shown).

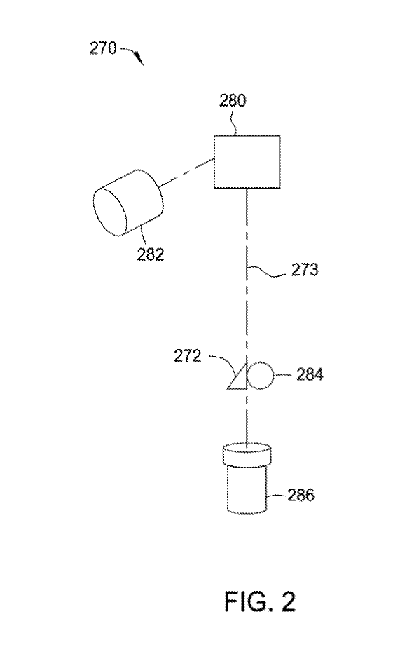

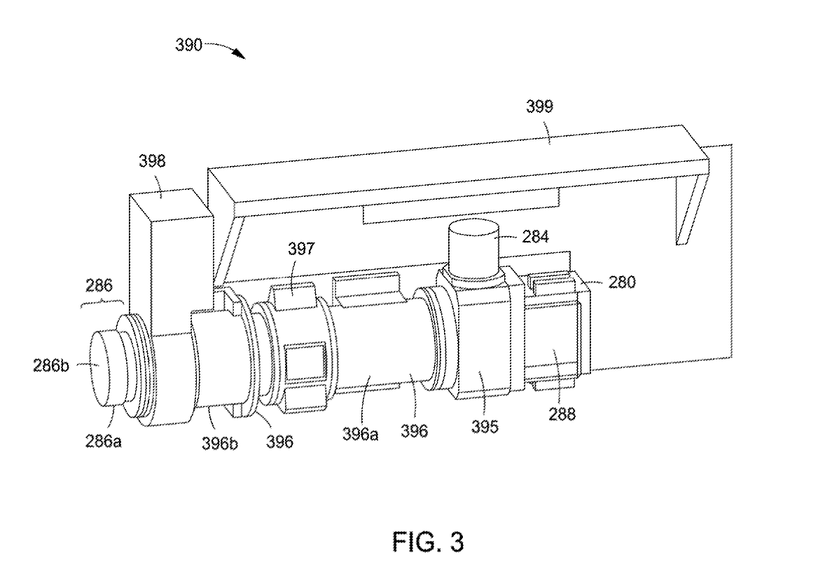

The processing apparatus 160 may include a support 162 and a processing unit 164. The support 162 may be disposed on the slab 120 and may include an opening 166 for the two or more stages 130 to pass under the processing unit 164. The processing unit 164 may be supported by the support 162. In one embodiment, the processing unit 164 is a pattern generator configured to expose a photoresist in a photolithography process. In some embodiments, the pattern generator may be configured to perform a maskless lithography process. The processing unit 164 may include a plurality of illumination tools (shown in FIGS. 2-3). In one embodiment, the processing unit 164 may contain 84 illumination tools. Each illumination tool is disposed in a case 165. The processing apparatus 160 may be utilized to perform maskless direct patterning. During operation, one of the two or more stages 130 moves in the X-direction from a loading position, as shown in FIG. 1, to a processing position. The processing position may refer to one or more positions of the stage 130 as the stage 130 passes under the processing unit 164. During operation, the two or more stages 130 may be lifted by a plurality of air bearings (not shown) and may move along the pair of tracks 124 from the loading position to the processing position. A plurality of vertical guide air bearings (not shown) may be coupled to each stage 130 and positioned adjacent an inner wall 128 of each support 122 in order to stabilize the movement of the stage 130. Each of the two or more stages 130 may also move in the Y-direction by moving along a track 150 for processing and/or indexing the substrate 140. Each of the two or more stages 130 is capable of independent operation and can scan a substrate 140 in one direction and step in the other direction. In some embodiments, when one of the two or more stages 130 is scanning a substrate 140, another of the two or more stages 130 is unloading an exposed substrate and loading the next substrate to be exposed.

A metrology system measures the X and Y lateral position coordinates of each of the two or more stages 130 in real time so that each of the plurality of image projection apparatuses can accurately locate the patterns being written in a photoresist covered substrate. The metrology system also provides a real-time measurement of the angular position of each of the two or more stages 130 about the vertical or Z-axis. The angular position measurement can be used to hold the angular position constant during scanning by means of a servo mechanism or it can be used to apply corrections to the positions of the patterns being written on the substrate 140 by the image projection apparatus 390. These techniques may be used in combination.

FIG. 2 is a perspective schematic view of an illumination tool system 270 according to one embodiment. The illumination tool system 270 may include a micro light emitting diode (microLED) array 280, a focus sensor 284, a projection lens 286, and a camera 272. The microLED array 280, the focus sensor 284, the projection lens 286, and the camera 272 may be part of an illumination tool 390 (shown in FIG. 3). The microLED array 280 includes one or more microLEDs with each microLED producing at least one light beam. The number of microLEDs may correspond to the resolution of the projected image. In one embodiment, the microLED array 280 includes 1920×1080 microLEDs, which represent the number of pixels of a high definition television. The microLED array 280 advantageously may act as a light source capable of producing a light having predetermined wavelength. In one embodiment, the predetermined wavelength is in the blue or near ultraviolet (UV) range, such as less than about 450 nm. The projection lens 286 may be a 10× objective lens.

During operation, a light beam 273 having a predetermined wavelength, such as a wavelength in the blue range, is produced by the microLED array 280. The microLED array 280 includes a plurality of microLEDs that may be controlled individually, and each microLED of the plurality of microLEDs of the microLED array 280 may be at “on” position or “off” position, based on the mask data provided to the microLED array 280 by the controller (not shown). The microLEDs that are at “on” position produce the light beam 273, i.e., forming the plurality of write beams 273, to the projection lens 286. The projection lens 286 then projects the write beams 273 to the substrate 140. The microLEDs that are at “off” position do not produce light. In another embodiment, the microLEDs that are at “off” position may produce a light beam that is directed to a light dump 282 instead of to the substrate 140. Thus, in one embodiment, the illumination tool contains the light dump 282.

FIG. 3 is a perspective view of an illumination tool 390 according to one embodiment. The illumination tool 390 is used to focus light to a certain spot on a vertical plane of a substrate 140 and to ultimately project an image onto that substrate 140. Throughput is a very important parameter of any lithography system. To achieve a high throughput, each illumination tool 390 may be designed to be as narrow as possible in at least one direction so that many illumination tools 390 can be packed together in the width of a substrate 140. As such, the microLED array 280 provides for both a light source and independent control of an image being projected. The illumination tool may include the microLED array 280, a beamsplitter 395, one or more projection optics 396a, 396b, a distortion compensator 397, a focus motor 398, and a projection lens 286. The projection lens 286 includes a focus group 286a and a window 286b.

In one embodiment, the light produced from the microLED array 280 may be directed to a light level sensor 393 so that the light level may be monitored. The actinic and broad-band light sources produced from the plurality of microLEDs in the microLED array 280 may be turned on and off independently of one another dependent upon the feedback from the light level sensor 393. In one embodiment, the light level sensor is coupled to a beamsplitter 395.

The beamsplitter 395 is used to further extract light for alignment. More specifically, the beamsplitter 395 is used to split the light into two or more separate beams. The beamsplitter 395 is coupled to the one or more projection optics 396. Two projection optics 296a, 296b are shown in FIG. 3.

Together the projection optics 396, the distortion compensator 397, the focus motor 398, and the projection lens 286 prepare for and ultimately project the image from the microLED array 280 onto the substrate 140. Projection optics 396a is coupled to the distortion compensator 397. The distortion compensator 397 is coupled to projection optics 396b, which is coupled to the focus motor 398. The focus motor 398 is coupled to the projection lens 286. The projection lens 286 includes a focus group 286a and a window 286b. The focus group 286a is coupled to the window 286b. The window 286b may be replaceable.

The microLED array 280, beamsplitter 395, one or more projection optics 396a, 396b and distortion compensator 397 are coupled to a mounting plate 399. The mounting plate 399 allows for precise alignment of the aforementioned components of the illumination tool 390. In other words, light travels through the illumination tool 390 along a single optical axis. This precise alignment along a single optical axis results in an apparatus that is compact. For example, the illumination tool 390 may have a thickness of between about 80 mm and about 100 mm. Accordingly, one benefit of the present disclosure is the ability to align multiple illumination tools in a single tool. Furthermore, each of the image projection apparatuses is easily removable and replaceable, resulting in reduced down time for maintenance.

In one embodiment, a focus sensor 284 and camera 272 are attached to the beamsplitter 395. The focus sensor 284 and camera 272 may be configured to monitor various aspects of the imaging quality of the image projection apparatus 390, including, but not limited to, through lens focus and alignment, as well as mirror tilt angle variation. Additionally, the focus sensor 284 may show the image, which is going to be projected onto the substrate 140. In further embodiments, the focus sensor 284 and camera 272 may be used to capture images on the substrate 140 and make a comparison between those images. In other words, the focus sensor 284 and camera 272 may be used to perform inspection functions.

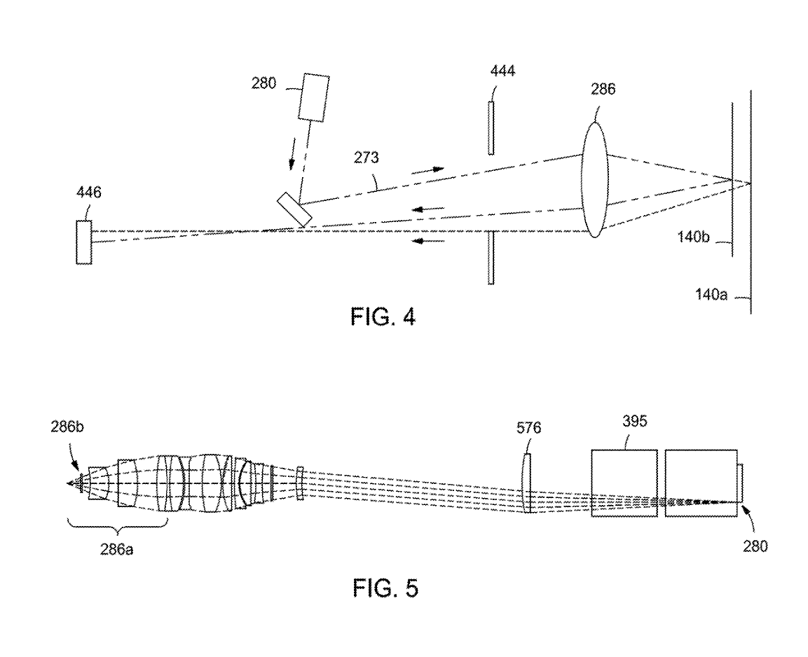

Specifically, as shown in FIG. 4, a narrow light beam 273 is directed through one side of the pupil 444 in the projection lens 286. The light beam 273 strikes the substrate 140 at an oblique angel and is reflected back so that it traverses the opposite side of the pupil 444. An image projection detector 446 accurately measures the lateral position of the return image. A change in the focus position of the substrate 140 causes the image position on the detector 446 to change. The change is proportional to the amount of defocus and the direction of image motion. Any deviation from the nominal position is converted into an analogue signal, proportional to the deviation, which is used to change the position of the projection lens 286, which brings the defocused substrate 140a back into good focus, shown as substrate 140b. In one embodiment, the focus sensor 284 and camera 272 are attached to the top surface of the beamsplitter 395.

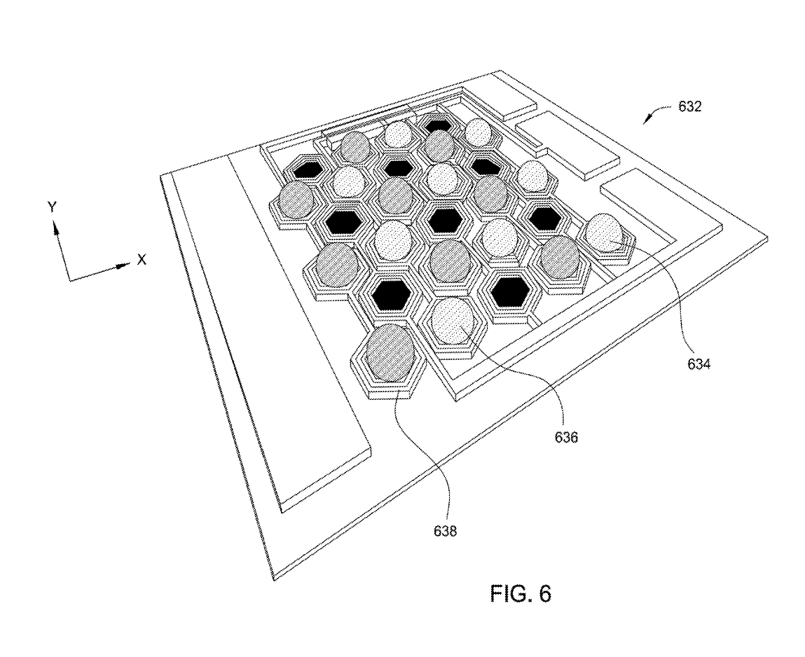

FIG. 5 is a cross-sectional view of the optical relays according to one embodiment. The optical relay may include a microLED array 280, a beamsplitter 395, a lens 576, and projection lens 286 which may include a focus group 286a and window 286b. The microLED array 280 is the imaging device of the illumination tool 390. The microLED array 280 includes a plurality of microLEDs 634 arranged in an array 632 (as shown in FIG. 6). The edges of microLEDs 634 are arranged along orthogonal axes, which may be the X axis and the Y axis. These axes are congruent with similar axis referenced to the substrate 140 or a stage coordinate system. These microLEDs 634 can be switched between on and off positions by varying the energy output to each microLED. In one embodiment, the unused light is directed to and stored in a light dump 282, as shown in FIG. 2. The microLED array 280 is positioned to be flat to the projection of the substrate 140.

Device packaging 636 are used to adjust and focus the incidence angle of the illumination beam from the microLEDs so the “on” beam is aimed down the center of the illumination tool 390 and the image created in the illumination system is centered. The device packaging 636 may include standard 3 mm, 5 mm, 10 mm, or other diameter lens sizes. The device packaging 636 may be an epoxy lens, reflector cup, or dome. The micro-LED array may also include wire bonds, and metal leads 638. Each microLED can emit a light covering ultraviolet (UV), blue and green wavelength range. One or more microLEDs with red, green, and blue colors fabricated from different semiconductors, or pixel blending, can be packaged within the same microLED array.

Use of the MicroLED array in the illumination tool help to minimize the footprint of each illumination tool by keeping the direction of the flow of illumination roughly normal to the substrate and eliminating the need for a two system tool which includes a light system and projection system. Instead, the light generation and projection system can be advantageously coupled into one.

While the foregoing is directed to embodiments of the present disclosure, other and further embodiments of the disclosure may be devised without departing from the basic scope thereof, and the scope thereof is determined by the claims that follow.

What is claimed is:

1. An illumination tool, comprising:
a microLED array, wherein the microLED array comprises one or more microLED, wherein each microLED produces at least one light beam;
a beamsplitter adjacent the microLED array;
one or more refractory lens components adjacent the beamsplitter; and
a projection lens adjacent the one or more refractory lens components.

2. The illumination tool of claim 1, wherein the projection lens further comprises:
a focus group; and
a window.

3. The illumination tool of claim 2, further comprising:
a focus sensor; and
a camera.

4. The illumination tool of claim 3, wherein the focus sensor and camera are disposed adjacent the beamsplitter.

5. The illumination tool of claim 4, further comprising:
a light dump.

6. The illumination tool of claim 5, further comprising:
a light level sensor.

7. The illumination tool of claim 6, further comprising:
a distortion compensator.

8. The illumination tool of claim 7, wherein the distortion compensator is disposed between the projection lens and the beamsplitter.

9. An illumination tool, comprising:
a microLED array, wherein the microLED array comprises one or more microLED, wherein each microLED produces at least one light beam;
a beamsplitter adjacent the microLED array;
one or more refractory lens components adjacent the beamsplitter;
a projection lens adjacent the one or more refractory lens components; and
a distortion compensator disposed between the projection lens and the beamsplitter.

10. The illumination tool of claim 9, wherein the projection lens further comprises:
a focus group; and
a window.

11. The illumination tool of claim 10, further comprising:
a focus sensor; and
a camera.

12. The illumination tool of claim 11, wherein the focus sensor and camera are coupled orthogonally to the beamsplitter.

13. The illumination tool of claim 12, further comprising:
a light dump.

14. The illumination tool of claim 13, further comprising:
a mounting plate, wherein the frustrated cube assembly, the microLED array, the beamsplitter, and the one or more refractory lens components are coupled to the mounting plate.

15. The illumination tool of claim 14, further comprising:
a light level sensor.

16. An illumination tool system, comprising:
two or more stages, wherein the two or more stages are configured to hold one or more substrates; and
a plurality of illumination tools for patterning the one or more substrates, wherein each illumination tool comprises:
a microLED array, wherein the microLED array comprises one or more microLED, wherein each microLED produces at least one light beam;
a beamsplitter adjacent the microLED array;
one or more refractory lens components adjacent the beam splitter; and
a projection lens adjacent the one or more refractory lens components.

17. The illumination tool system of claim 16, wherein the projection lens further comprises:
a focus group; and
a window.

18. The illumination tool system of claim 17, further comprising:
a focus sensor; and
a camera.

19. The illumination tool system of claim 18, wherein the focus sensor and camera are coupled orthogonally to the beamsplitter.

20. The illumination tool system of claim 19, further comprising:
a light dump.
